(19) United States
(12) Patent Application Publication
(10) Pub. No.: US 2012/0196453 A1
(43) Pub. Date: Aug. 2, 2012

(54) Systems and Methods for Susceptor Assisted Microwave Annealing

(75) Inventor: Terry L. Alford, Phoenix, AZ (US)

(73) Assignee: Arizona Board of Regents for and on Behalf of Arizona State University, Scottsdale, AZ (US)

(21) Appl. No.: 13/363,909

(22) Filed: Feb. 1, 2012

Related U.S. Application Data
(60) Provisional application No. 61/438,515, filed on Feb. 1, 2011.

(51) Int. Cl. H01L 21/263; H05B 6/64

(52) U.S. Cl. 438/795; 219/678; 257/E21.333

(57) ABSTRACT

Systems and methods for microwave annealing are disclosed. In some embodiments, the system may comprise a microwave emitter configured to emit a microwave at a single frequency during an anneal time. In some embodiments, the system may further comprise an anneal unit to be annealed, the anneal unit having a top side, a bottom side, and one or more edge sides. In some embodiments, the system may further comprise a susceptor configured to absorb microwave energy, where the susceptor is adjacent to the edge side and at the bottom side of the anneal unit.

### CROSS-REFERENCE TO RELATED APPLICATIONS

This application claims priority to U.S. Provisional Application No. 61/438,515 filed Feb. 1, 2011, the entire contents of which are incorporated herein by reference.

### BACKGROUND OF THE INVENTION

1. Field of the Invention

This invention relates to semiconductors and more particularly relates to systems and methods for susceptor assisted microwave annealing of semiconductors.

2. Description of the Related Art

Thin crystalline silicon (Si) films have gained increased importance in the semiconductor industry since the advent of the thin film transistors (TFTs) in the 1980s. The crucial regions such as drain/source in ultra-shallow transistors may too require thin crystalline layers that are doped, in order to provide the necessary conductivity in these regions. But doping may damage the surface of these already thin films and may amorphize them. Post implant processes should not allow for extensive dopant diffusion. It may be necessary to repair this damage to make the films crystalline, and electrically activate the dopants for the devices to function as desired. Different kinds of post implantation annealing techniques are used: solid phase epitaxy (SPE), laser annealing, rapid thermal annealing (RTA), and metal induced crystallization (MIC). A temperature of above 600° C. may be required to achieve high quality crystalline substrates (e.g., Si), which primitively took long hours. MIC may crystallize substrates (e.g., Si) at lower temperatures and shorter duration, but runs the risk of contamination and disintegration of the film. Laser annealing, though used earlier extensively, provides uneven heating of the sample.

Metal alloy thin films may also be annealed to manipulate the their sheet resistance and/or the grain size of the metals, which in turn manipulates the electrical conductivity of the metal alloy thin films. Traditional annealing processes, such as vacuum annealing, for metal alloy thin films suffer from poor performance and a very long anneal time is required.

### SUMMARY OF THE INVENTION

Systems configured to anneal are disclosed. In some embodiments the system may comprise a microwave emitter configured to emit a microwave at a single frequency during an anneal time. In some embodiments, the system may further comprise an anneal unit having a top side, a bottom side, and one or more edge sides. In some embodiments, the system may further comprise a susceptor configured to absorb microwave energy, where the susceptor is adjacent to the one or more side edges and at the bottom side of the anneal unit.

In some embodiments, the single frequency may be 2.45 GHz. In some embodiments, the anneal time is less than two minutes. In some embodiments, the system may be configured to heat the top side of the cylindrical substrate to at least 600° C. In some embodiments, the system may comprise a temperature measuring device.

In some embodiments, the anneal unit may be a cylindrical substrate having a top side, a bottom side, and a circumferential edge. In some embodiments, the cylindrical substrate may comprise a dopant. For example, in some embodiments, the dopant may comprise arsenic (As), boron (B), silicon (Si); and aluminum (Al). In some embodiments, the cylindrical substrate may substantially comprise Si. In some embodiments, the susceptor may comprise SiC. In some embodiments, the susceptor may comprise SiC-coated alumina; magnesium oxide (MgO) coated alumina; SiC coated quartz; and MgO coated quartz.

In some embodiment, the anneal unit may be a metal alloy thin film having a top side, a bottom side, and one or more side edges. In some embodiments, the metal alloy thin film may comprise silver (Ag) and copper (Cu). In some embodiments, the metal alloy thin may film comprise any combination of metals.

Methods are also disclosed. In some embodiments, the method for annealing may comprise receiving an anneal unit having a top side, a bottom side, and one or more side edges. In some embodiments, the method may comprise arranging a susceptor configured to absorb microwave energy such that the susceptor is adjacent to the one or more side edges and the bottom side of the anneal unit. In some embodiments, the method may further comprise starting a single-frequency microwave emitter configured to heat both the susceptor and the anneal unit during an anneal time. In some embodiments, the method may further comprise stopping the single-frequency microwave emitter after the top side of the anneal unit has reached a specified temperature.

In some embodiments, the anneal unit may be a cylindrical substrate having a top side, a bottom side, and a circumferential edge. In some embodiments, the anneal unit may be a metal alloy thin film having a top side, a bottom side, and one or more side edges.

In some embodiments, the method may further comprise measuring the temperature on the top side of the substrate.

The term “coupled” is defined as connected, although not necessarily directly, and not necessarily mechanically.

The terms “a” and “an” are defined as one or more unless this disclosure explicitly requires otherwise.

The term “substantially” and its variations are defined as being largely but not necessarily wholly what is specified as understood by one of ordinary skill in the art, and in one non-limiting embodiment “substantially” refers to ranges within 10%, preferably within 5%, more preferably within 1%, and most preferably within 0.5% of what is specified.

The terms “comprise” (and any form of comprise, such as “comprises” and “comprising”), “have” (and any form of have, such as “has” and “having”), “comprise” (and any form of comprise, such as “comprises” and “including”) and “contain” (and any form of contain, such as “contains” and “containing”) are open-ended linking verbs. As a result, a method or device that “comprises,” “has,” “comprises” or “contains” one or more steps or elements possesses those one or more steps or elements, but is not limited to possessing only those one or more elements. Likewise, a step of a method or an element of a device that “comprises,” “has,” “comprises” or “contains” one or more features possesses those one or more features, but is not limited to possessing only those one or more features. Furthermore, a device or structure that is configured in a certain way is configured in at least that way, but may also be configured in ways that are not listed.

Other features and associated advantages will become apparent with reference to the following detailed description of specific embodiments in connection with the accompanying drawings.

### BRIEF DESCRIPTION OF THE DRAWINGS

The following drawings form part of the present specification and are comprised to further demonstrate certain aspects of the present invention. The invention may be better understood by reference to one or more of these drawings in combination with the detailed description of specific embodiments presented herein.

FIG. 1A illustrates one embodiment of a system for susceptor assisted microwave annealing;

FIG. 1B illustrates a top view of an embodiment of a substrate and a susceptor;

FIG. 1C illustrates a cross-section view of an embodiment of a substrate and susceptor;

FIG. 1D illustrates the top side, bottom side, and circumferential edge of a substrate;

FIG. 1E illustrates one embodiment of a system for susceptor assisted microwave annealing;

FIG. 2A illustrates one embodiment of a method to heat an object using microwave annealing;

FIG. 2B illustrates the impact of a susceptor when used in conjunction with microwave annealing;

FIG. 3A illustrates Raman spectroscopy results of an arsenic implanted Si substrate;

FIG. 3B illustrates Raman spectroscopy results of a Si implanted Si substrate;

FIG. 4 illustrates ion-channeling of arsenic implanted Si;

FIG. 5A illustrates sheet resistance drops with annealing times for arsenic implanted Si;

FIG. 5B illustrates sheet resistance drops with annealing times for Si implanted Si;

FIG. 6 illustrates XTEM images of Si implanted with arsenic (a) as-implanted, (b) after 40 seconds microwave anneal, and (c) after 70 seconds microwave anneal; and

FIG. 7. illustrates SIMS for arsenic implanted Si.

FIG. 8. illustrates the sheet resistances of the Ag—Cu thin films increase as the concentration of Cu increases.

FIG. 9. illustrates the grain sizes of Ag in the Ag—Cu thin films drop as the atomic fraction of Cu increases.

FIG. 10 illustrates X-ray diffraction results depicting the Ag grain growth in the Ag—Cu thin film as a result of a thermal anneal and a microwave anneal.

### DETAILED DESCRIPTION

Various features and advantageous details are explained more fully with reference to the nonlimiting embodiments that are illustrated in the accompanying drawings and detailed in the following description. Descriptions of well known starting materials, processing techniques, components, and equipment are omitted so as not to unnecessarily obscure the invention in detail. It should be understood, however, that the detailed description and the specific examples, while indicating embodiments of the invention, are given by way of illustration only, and not by way of limitation. Various substitutions, modifications, additions, and/or rearrangements within the spirit and/or scope of the underlying inventive concept will become apparent to those skilled in the art from this disclosure.

In embodiments of the disclosed invention, microwave annealing (e.g., by using a SiC susceptor/assistor) is used to achieve a high quality crystalline substrate layer (e.g., Si), or a thin film with better grain growth (e.g. Ag—Cu film) in much shorter times. Magnesium oxide (MgO) and silicon carbide (SiC) and other like materials have dielectric properties that are suitable for microwave absorption. Other materials, such as silicon nitride (Si₃N₄) and alumina (Al₂O₃), are poor absorbers of microwaves up to a critical temperature (T_{C}). At temperatures above T_{C}, the dielectric loss factor begins to increase, and the material begins to absorb the microwaves. In a similar manner an implanted substrate (e.g., Si) must reach a T_{C}, temperature before it absorbs efficiently. Before reaching the critical temperature, these materials have very low loss factors; hence they become heated very slowly in the microwave field.

Hybrid heating can be used to help process materials like Si that exhibit temperature dependent absorption. For these cases, the material is heated through traditional conduction heat transfer prior to reaching the critical temperature T_{C}. Once this critical temperature is reached, the material's loss factor increases and the material begins to couple more effectively with microwaves.

Hybrid heating can also be used to help process materials typically too thin to absorb microwave radiation (e.g., Au—Cu thin films). For these cases, the films can be heated rapidly.

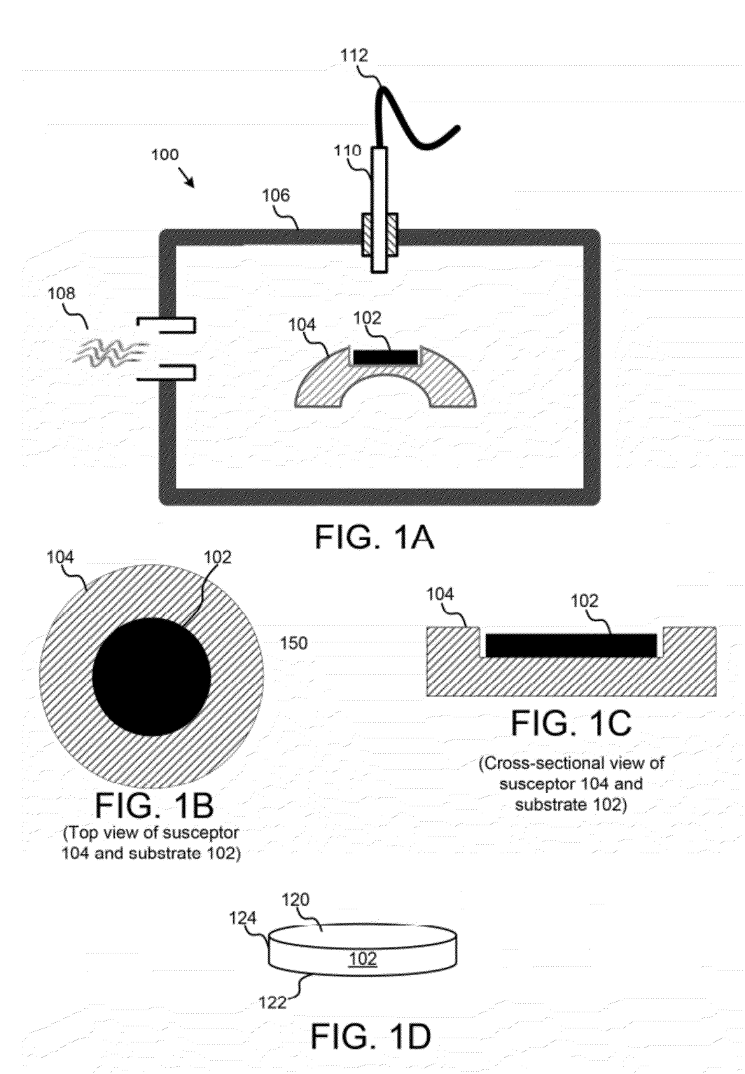

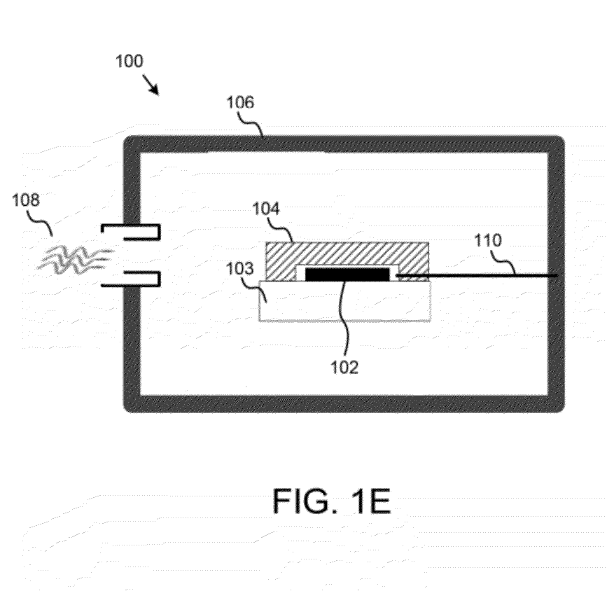

FIG. 1A illustrates one embodiment of a system 100 for microwave annealing. In one embodiment, the system 100 comprises a microwave emitter configured to emit microwaves 108 at a single frequency during an anneal time. A microwave emitter may comprise a microwave tube, an antenna, or other like device known in the art. In some embodiments, the microwave emitter may emit microwaves 108 into a microwave chamber/cavity 106. The microwave emitter may be configured to emit microwaves 108 at a single frequency substantially close to 2.45 GHz.

In some embodiments, the system 100 may comprise an anneal unit 102. In one embodiment, the anneal unit 102 may have a top side, a bottom side, and one or more edge sides. FIG. 1D illustrates the top side 120, bottom side 122, and edge side 124 of an anneal unit 102. In some embodiments, the top side and bottom side may be reversed. For example, 122 may represent the top side and 120 may represent the bottom side.

In some embodiments, the anneal unit 102 may be a substrate. As is common with substrates used in semiconductor applications, the substrate may be cylindrical. The cylindrical substrate may have a circumferential edge side 124, as shown in FIG. 1D. In some embodiments, the substrate may substantially comprise Si and/or silicon carbide (SiC). In such embodiments, the substrate may be doped with a dopant. For example, the dopants may comprise arsenic (As), boron (B), silicon (Si), and aluminum (Al) Specific embodiments of dopants and substrates comprise As in Si, B in Si, Si in Si, and Al in SiC.

In some embodiments, the anneal unit 102 may be a thin film. In some embodiments, the thin film may be cylindrical as shown in FIG. 1D. In some embodiments, the thin film may be rectangular parallelepiped or the like, with a top side, a bottom side, and a plurality of edge sides. In some embodiments, the thin film may be a metal alloy thin film. In one embodiment, the metal alloy thin film may substantially comprise silver (Ag) and copper (Cu). In some embodiments, the metal alloy thin film may comprise any suitable combinations of metals.

In some embodiments, the system 100 may further comprise a susceptor 104 configured to absorb microwave energy, where the susceptor 104 is adjacent to the edge sides and at the bottom side of the anneal unit 102. Susceptors may be described as materials that have dielectric properties that are suitable for microwave absorption. Specific embodiments of susceptors 104 comprise SiC, SiC coated alumina, MgO coated alumina, SiC coated quartz, and MgO coated quartz.

FIGS. 1A, 1B, 1C, and 1E each show embodiments of the orientation of the anneal unit 102 and a susceptor 104. As shown in FIG. 1A, the susceptor 104 takes the shape of an upside-down bowl, and the anneal unit 102 is placed in an opening on top of the susceptor 104. As such, the bottom side of the anneal unit 102 is adjacent to the susceptor 104. Additionally, the edge side of the anneal unit 102 is also adjacent to the susceptor 104. FIG. 1B shows a top view of this arrangement of anneal unit 102 and susceptor 104. FIG. 1C shows an additional embodiment of the anneal unit 102 and susceptor 104. As shown here, instead of a bowl shape, the susceptor 104 is more rectangular in form. Significantly, however, the bottom side of the anneal unit 102 and the edge sides of the anneal unit 102 may be adjacent to the susceptor 104.

FIG. 1E shows an additional embodiment of the anneal unit 102 and susceptor 104. Here, the orientation of the susceptor 104 and the anneal unit 102 are reversed—the susceptor 104 is above the anneal unit 102. As shown, anneal unit 102 may sit on a base 103. The base 103 may be quartz or other like material. In some embodiments, the base 103 may comprise a susceptor 104.

In some embodiments, the system 100 may further comprise a temperature measuring device 110. The temperature measuring device 110 may comprise a pyrometer, thermocouple, or other like devices. In some embodiments, the temperature measuring device 110 may be further connected to a computing device (e.g., computer, workstation, server, or other like device) to log the temperature readings through a thermocouple 112. As shown, the temperature measuring device 110 in some embodiments may be at the top of the chamber 106. In other embodiments, the temperature measuring device 110 may be on any side of the chamber 106—or located within the chamber 106 itself. For example, in the embodiments where the susceptor 104 is on top of the anneal unit 102 as shown in FIG. 1E, the temperature measuring device 110 may be found on the other side of the chamber 106. In the figure, thermocouple 112 is located inside the chamber 106. Such an embodiment may allow for variable microwave frequencies to be used.

In some embodiments of the system 100, the microwave emitter may be turned on for an anneal time of a specified time. As described later in the disclosure, the anneal time may range from 40 to 100 seconds. Generally, as described in the disclosure, the susceptor assisted microwave anneal time is around or less than two minutes. In such embodiments, the microwave emitter may be turned off after the specified anneal time. Also as described in more detail throughout the example sections, the result of the microwave anneal is that the top side of the anneal unit will be rapidly heated. In some embodiments, the system 100 may be configured to heat the top side 120 of the anneal unit 102 to at least 600° C. In other embodiments, the system 100 may be configured to heat the top side 120 of the anneal unit 102 to at least 450° C.

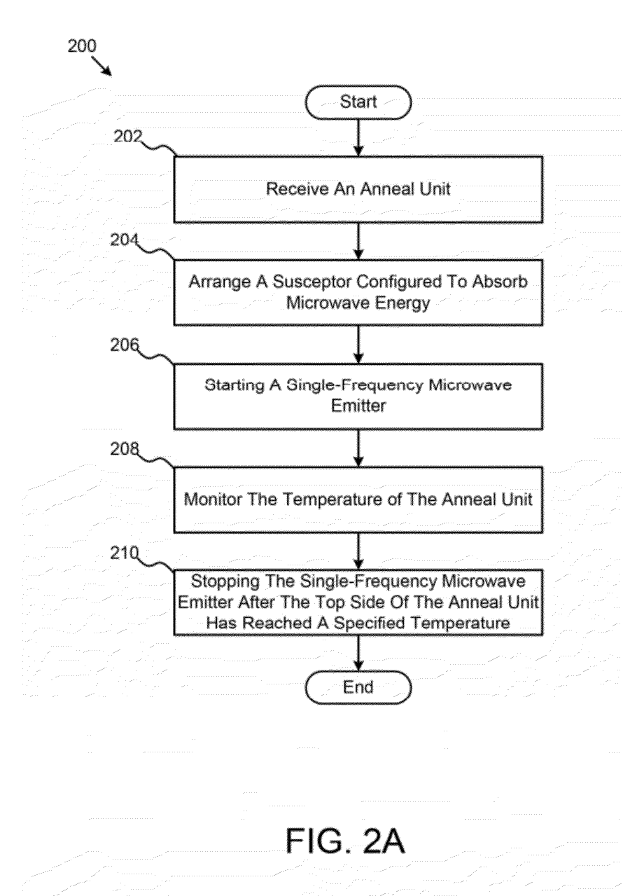

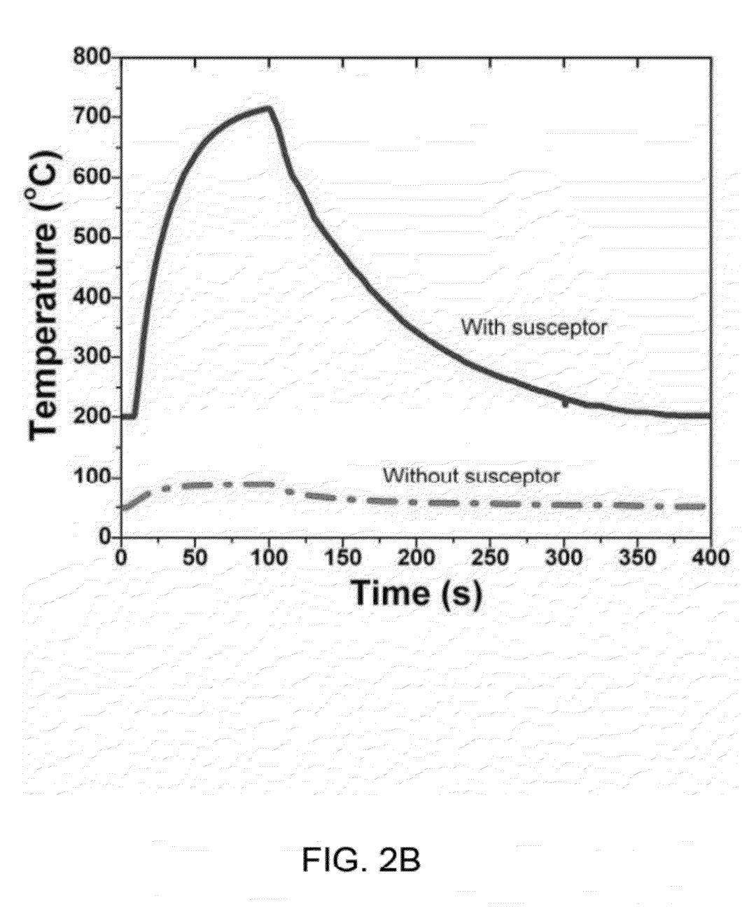

FIG. 2A shows a method 200 to anneal an anneal unit using the system 100. In one embodiment, the method 200 comprises receiving an anneal unit 202. The anneal unit may be a substrate or thin film described above, where the anneal unit may have a top side, a bottom side, and one or more edge sides. In one embodiment, the method 200 may further comprise arranging a susceptor 204 configured to absorb microwave energy. The susceptor may be arranged to be adjacent to the one or more edge sides and the bottom side of the anneal unit. In one embodiment, the method 200 may comprise starting a single-frequency microwave emitter 206. The single-frequency microwave emitter may be configured to heat both the susceptor and the anneal unit during an anneal time.

In one embodiment, the method 200 may further comprise monitoring the temperature of the anneal unit 208. In one embodiment, the temperature of the top side of the anneal unit may be measured. The temperature of the anneal unit may be measured by a temperature measuring device, which may comprise a pyrometer, thermocouple, or other like device. The temperature of the anneal unit may be further monitored by a computing device (e.g., computer, workstation, server, or other like device) connected to a thermocouple, which is in turn connected to the temperature measuring device. In one embodiment, the method 200 may further comprise stopping the single-frequency microwave emitter after the top side of the anneal unit has reached a specified temperature 210.

### Example 1

Microwave annealing of different dosage arsenic implanted Si samples was done in a single-frequency (2.45 GHz), 2.8×10⁴ cm³ cavity applicator microwave system equipped with a 1300 Watt magnetron source, with annealing times of 40, 70, and 100 seconds for each sample type. A Raytek Compact MID series pyrometer with a spectral response of 8-14 μm was used to monitor the near surface temperature. The emissivity for the samples was adjusted by careful calibration of the temperature read by the pyrometer against the temperature monitored by a thermocouple. For the arsenic implanted samples, the surface temperatures ranged from 620-680° C. FIG. 2B shows a typical plot of temperature of two samples versus anneal time for 1×10¹⁵ As⁺ cm⁻² samples which were microwave annealed for 100 s. The anneal time is defined as the duration between when the microwave is switched on and when the microwave is turned off.

For the first sample, the annealing of the samples was assisted by silicon carbide (SiC) susceptors, to allow dopant activation and SPE. For the second sample, no susceptor was used. As shown, without the susceptor, the implanted Si fails to reach a temperature greater than 100° C. Previous work using susceptor assisted annealing suggests that susceptor absorbs the microwave radiation and supplies additional heat to the sample.

The as-implanted As⁺ and the microwave annealed samples were characterized using several methods to test for dopant activation and film recrystallization. A Raman line scan was performed to determine the structure of the As⁺ implanted Si pre and post microwave annealing. An argon laser with an excitation wavelength of 532 nm was focused onto the samples mounted underneath the optical microscope, through an Olympus 100×0.8 NA objective. The collected spectra from the sample are reflected into a Sopra 2000 2 m double spectrometer by a 50% beam-splitter. A 532 nm notch filter blocks any scattered light from the laser. The spectrum is dispersed and collected into a Princeton CCD Camera with an energy dispersion of 60 pixels/cm-1. The Raman spectra collected from the CCD is calibrated as a function of intensity that depends on the time of exposure, against the relative wave number.

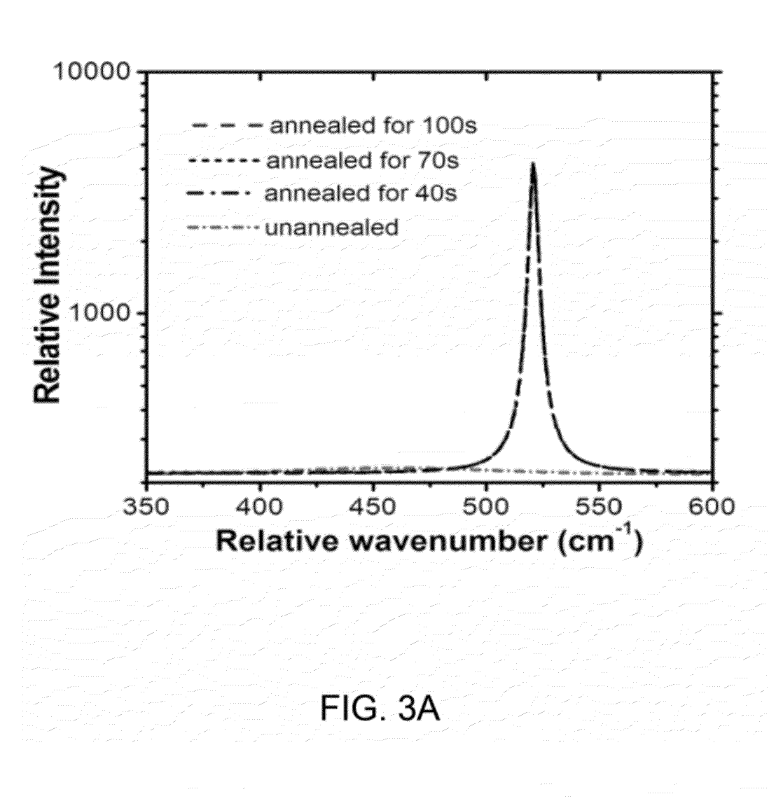

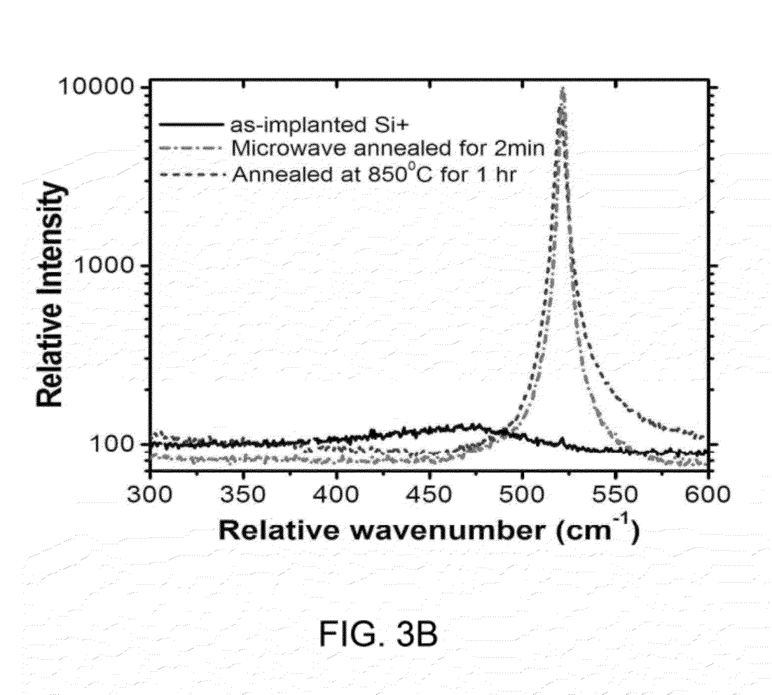

FIG. 3A shows the Raman analysis of the as-implanted and annealed samples of 1×10¹⁵ cm⁻² dose arsenic implanted with energy of 180 keV, where Si is used as the substrate and As⁺ is used as the dopant. The 480 cm⁻¹ broad peak is attributed to the amorphous Si layer of the unannealed samples. The Raman spectra of the annealed samples, however, does not possess this peak, and instead possesses a 520 cm⁻¹ single crystal Si peak, indicating that the crystallization of the as-implanted layer was not only initiated, but also completed within 40 s of the microwave anneal.

FIG. 3B shows the Raman analysis from a Si substrate implanted with 75 keV, 2×10¹⁵ Si⁺ cm⁻²—thus, with a Si substrate and Si⁺ dopant. As shown in FIG. 3B, the two minute microwave anneal results in a sharper peak and is indicative of better crystalline quality when compared to a conventional one hour thermal process.

Secondary ion mass spectroscopy (SIMS) using a low energy electron gun was performed to capture the secondary As⁺ ions from the sample across its depth, which was done by an energy and mass selection by the first electronic analyzer. The results, observed as a function of the yield with time, were calibrated to give a measure of the density of As⁺ across the depth of the sample. The plot of density vs. depth helps observe the dopant profile inside the sample, and by comparison, gives the extent of diffusion of the dopant for the microwave annealed samples vs. RTA annealed samples.

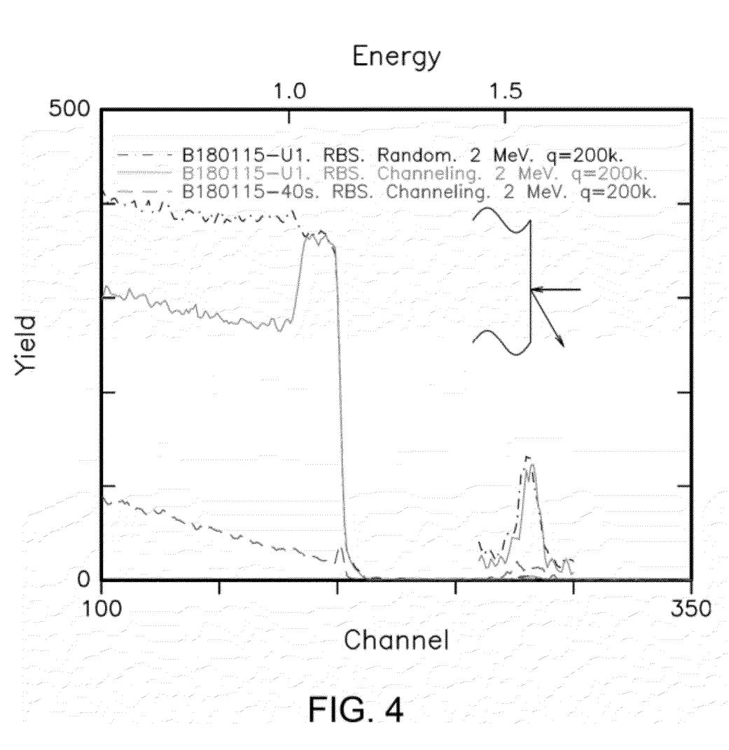

Ion implantation may cause implant damage. Ion channeling experiments were conducted to compare the damage in unannealed samples as opposed to processed samples, and to ascertain if the microwave annealing could repair a damage of this extent. Two of the spectra in FIG. 4 denote the RBS results of the as-implanted samples. First, the dotted B180115-U1 represents ion channeling of as-implanted As⁺ sample in random orientation. Second, the solid line represents ion channeling of as implanted As⁺ in channeling orientation. The energetic arsenic ions create a thin damaged Si layer and amorphize the crystalline Si. Both the plots show the lattice damage due to ion implantation, and also a magnified peak (×30) around channel number 280, that confirms arsenic is located in the interstitial sites instead of substitutional sites. A comparison of the normalized yield of aligned channeling spectrum against the normalized yield of random spectra gives the order of lattice damage. The factor is denoted by χₘᵢₙ. Third, the dotted B180115-40 s represents ion channeling of 180 keV 1×10¹⁵ cm⁻² arsenic implanted Si annealed for 40 s, in channeling orientation after 40 s microwave annealing. The χₘᵢₙ for (c) is 0.11 implying that the lattice damage was repaired to a great extent. The ion channeling yield of a 70 second annealed sample (not shown), also has a χₘᵢₙ of around 0.11 confirming that the improvement in lattice damage repair is insignificant over a 40 s microwave anneal. The results signify that the dopant atoms are now located in substitutional sites instead of interstitial sites, as in the second spectra. This repair of lattice damage, and dopant relocation, are key factors that lead to dopant activation and reduced sheet resistance of the arsenic implanted Si samples. The spectra of 180 keV arsenic implanted samples, confirms deeper lattice damage, and thicker damaged surface layer. However great the damage, a 40 s anneal would still suffice to repair the lattice implant damage, and distribute the dopant atoms to substitutional sites in the lattice.

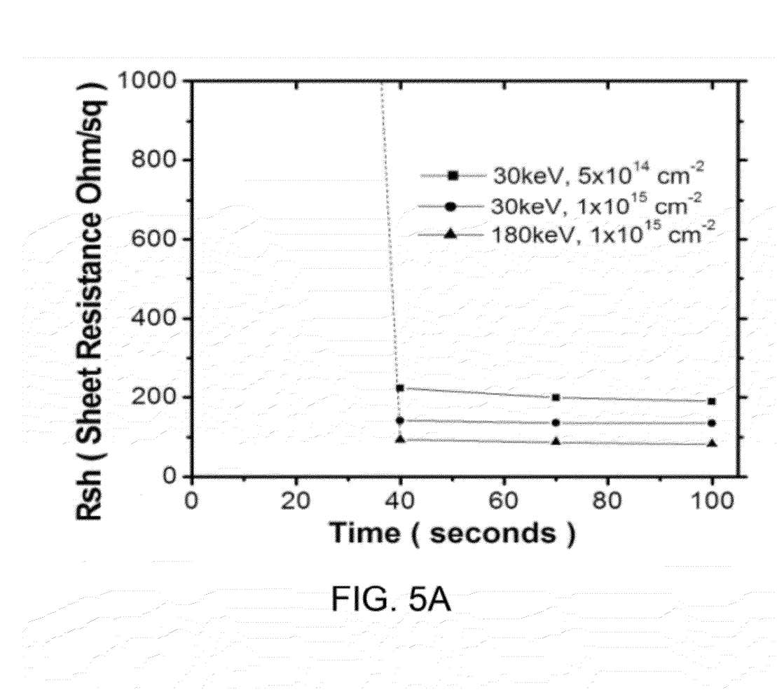

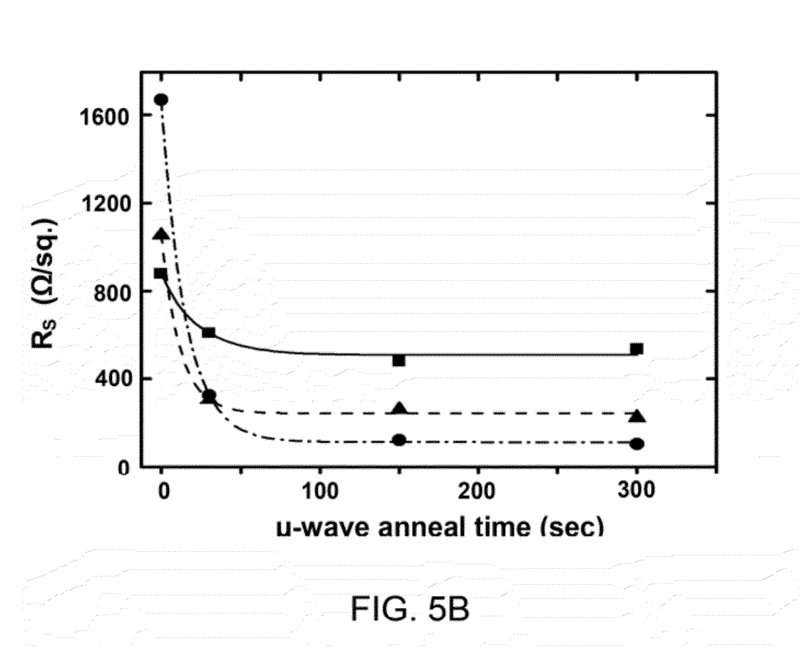

To test for any electrical dopant activation, the samples were placed face up under an in-line 4 point probe reading out to a 100 mA Keithley 2700 digital multimeter. The sheet resistances (Rₛₕ) of the samples were carefully tabulated for every process time. Analysis against the readings from the unannealed samples shows that almost complete dopant activation was achieved within a processing time of 40 s, beyond which there was no significant improvement. As shown in FIG. 5A, this applies to all three samples of different dosages of As⁺ and energies. Similarly, as shown in FIG. 5B, a similar sheet resistance analysis applies for Si implanted with (▪—1×10¹⁵, ▴—3×10¹⁵, and —5×10¹⁵) B⁺ cm⁻² (Boron).

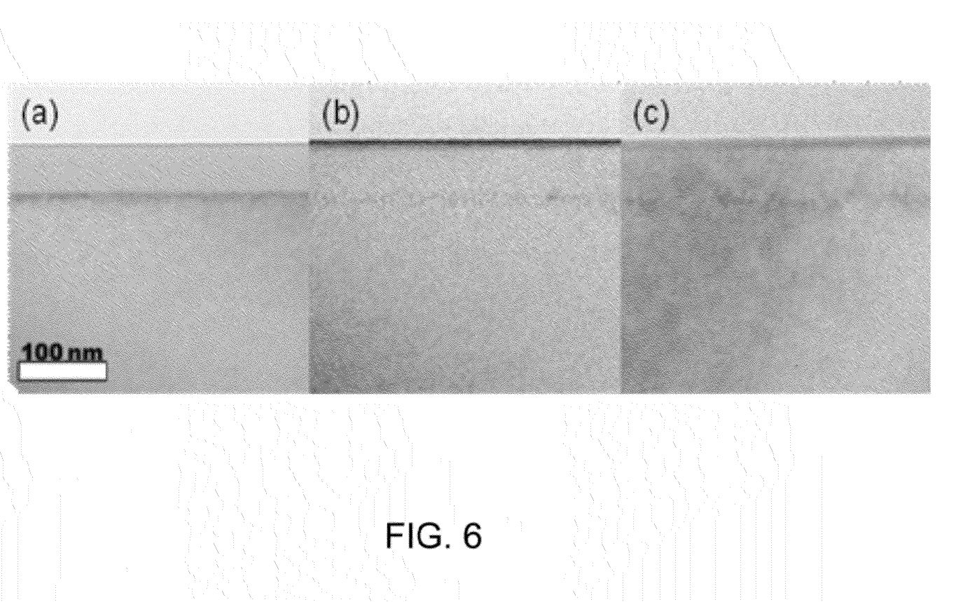

To observe the microstructure of the sample before and after annealing, a cross-section transmission electron microscopy (XTEM) was performed using a Philips CM200-FEG transmission electron microscope (TEM) at an operating voltage of 200 kV. The extent of recrystallization of the As⁺ doped Si surface can be viewed from the XTEM images as shown in FIG. 6. The amorphous layer in as-implanted sample is distinguished from the underlying crystalline layer, as a lightly shaded region. For the microwave annealed samples of 40 s, an amorphous layer is no more visible, and it supports the Raman spectra that the amorphous layer has been completely recrystallized. A 70 s annealing does not provide any better results, since complete recrystallization has already been achieved. A band of defects was observed at the depth where the amorphous-crystalline Si layer lies in the as-implanted samples. This may be due to the migration of the vacancies and precipitates to the interface while the surface is being recrystallized by nucleation in epitaxial fashion over the crystalline Si layer underneath. A 70 s anneal does not provide any better results, since complete recrystallization has already been achieved.

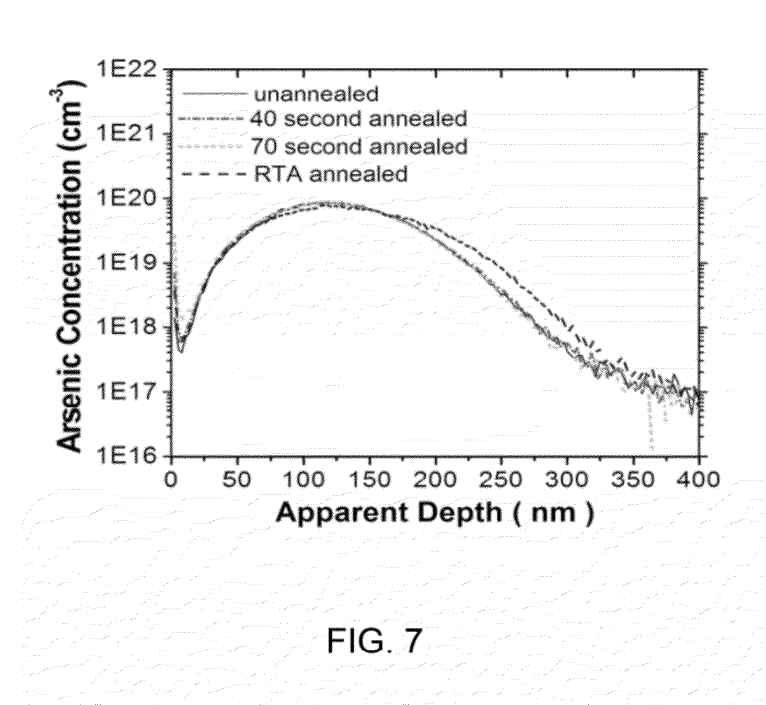

To assess the impact of microwave annealing on dopant diffusion, SIMS analysis was performed on a 900° C. RTA sample, annealed for 30 s, apart from the microwave annealed samples. As seen in FIG. 7, both 40 and 70 s microwave annealing on the samples shows minimal dopant diffusion across the depth. RTA on the sample shows greater dopant diffusion possibly as a result of energizing the As⁺ to diffuse into the sample.

A surface layer goes through incubation, before it can recrystallize due to nucleation from an underlying crystalline layer. Microwaves are capable of reducing the incubation time required, hence achieving SPEG in much less time. Microwaves supply high activation energy sufficient to repair the lattice damage and bring about dopant activation, without causing dopant diffusion, all in a short duration. The temperature of about 620° C. appears to be the key factor responsible for damage repair, but it is not enough to remove the defect bands after SPEG. From the XTEM images, a longer period of microwave annealing does not suffice to remove the defect band, which could be the only drawback among all of the recordings. To repair the defect network, an anneal temperature of 950° C. is required. The defect band observed was as a result of coagulation of deep level interstitials that remain from the vacancy-interstitial annihilation. Arsenic has a tendency of forming micro clusters, causing interstitials to be freed, that form dislocations at the depth of the arsenic implant damage. Unlike boron implanted Si, coalescing of excess vacancies at the surface of the As⁺ implanted layer was not observed.

For dopant activation of arsenic to be achieved, the As⁺ needs to replace Si in the substitutional sites. The ion channeling results also show that the dopant has replaced Si substitutionally implying successful dopant activation. However, the defect band can be a limiting factor to achieve this completely, since SPEG can be inhibited.

The mechanism underlying the heating of the sample through the susceptor, is microwave power loss. Microwave power converts into heat based on the property of the material defined as effective loss factor, which comprises conduction and polarization losses. In order to do so, the susceptor made up of a dielectric material, absorbs the microwave power, and supplies it to the sample. Arsenic being a high Z material requires higher temperature to absorb the microwaves necessary for lattice damage repair which are provided due to the use of the susceptor, making it an assisted annealing.

### Example 2

Two different annealing methods, microwave annealing and vacuum thermal annealing, were used to anneal Ag—Cu thin films, which can serve as a possible and reliable interconnect system. The thin films of Ag—Cu used here were deposited by co-sputtering. A sputter target of pure Ag and pure Cu were used. The base pressure of the sputter system before each deposition was approximately 1×10⁻⁷ Torr. The deposition was performed using pure Ar gas (99.999%) at a pressure of 10 mTorr. The dc power for Ag deposition was fixed at 50 W; whereas, the dc power for Cu deposition was varied. The thickness and composition of the Ag—Cu alloy films were determined using Rutherford backscattering spectrometry (RBS) with a General Ionex Tandetron accelerator. Samples were analyzed in a vacuum of less than 10⁻⁶ Torr using a 2.0 MeV He ion beam and the sample tilt angle was 8 degrees. The RUMP computer-simulation program was used to determine composition and thicknesses.

For microwave annealing process, the Ag—Cu films were subjected to a 2.45 GHz microwave frequency for one minute. The temperature during the annealing process was measured using a pyrometer. The maximum temperature reached during this process of microwaving was 70° C. Another set of Ag—Cu films were used and annealed under vacuum at 200° C. for 2 hours. The pressure inside the furnace was approximately 10⁹ Torr.

The sheet resistances of the Ag—Cu films were measured using Keithley 2700 data acquisition system. The resistivity of the Ag—Cu films were calculated using the following relation

ρ=Rₛₕ×t

where, Rₛₕ is the sheet resistance obtained from four point probe measurement and t is the linear thickness.

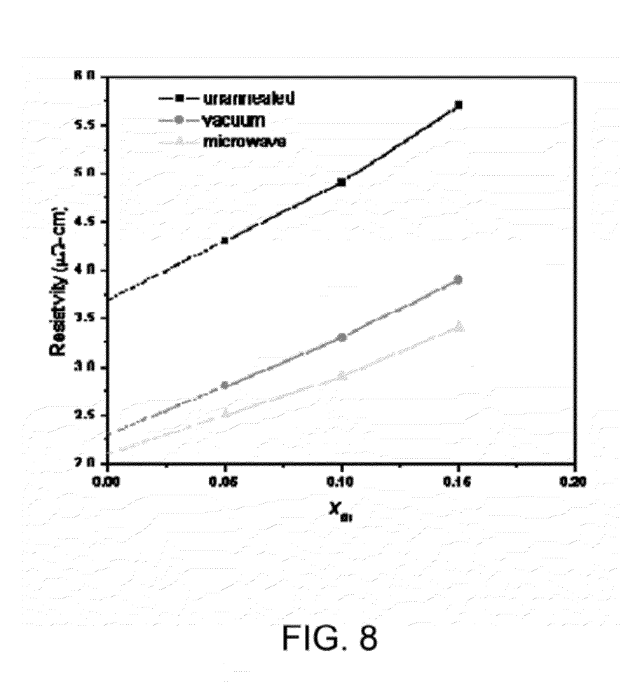

FIG. 8 shows that the resistivity increases with the increase of Cu concentration. After annealing the Ag—Cu films there was a notable decrease in resistivity. The lowering of resistivity is attributed to the increased grain size.

Phase formation and grain growth of the Ag—Cu films were investigated by X-ray diffraction (XRD) analysis using a Philips X'pertPro diffractometer with a Cu K_{α} radiation source. A working voltage of 45 kV was employed with a filament current of 40 mA. The Scherrer equation was used to determine the grain size of the Ag particles using the Ag (111) peak (full width at half maximum) FWHM values. The grain size d is given by

$$d = \frac{0.94 * λ}{FWHM * cos θ}$$

where, λ is the wavelength of the incident Cu K_{α} radiation (0.154056 nm)

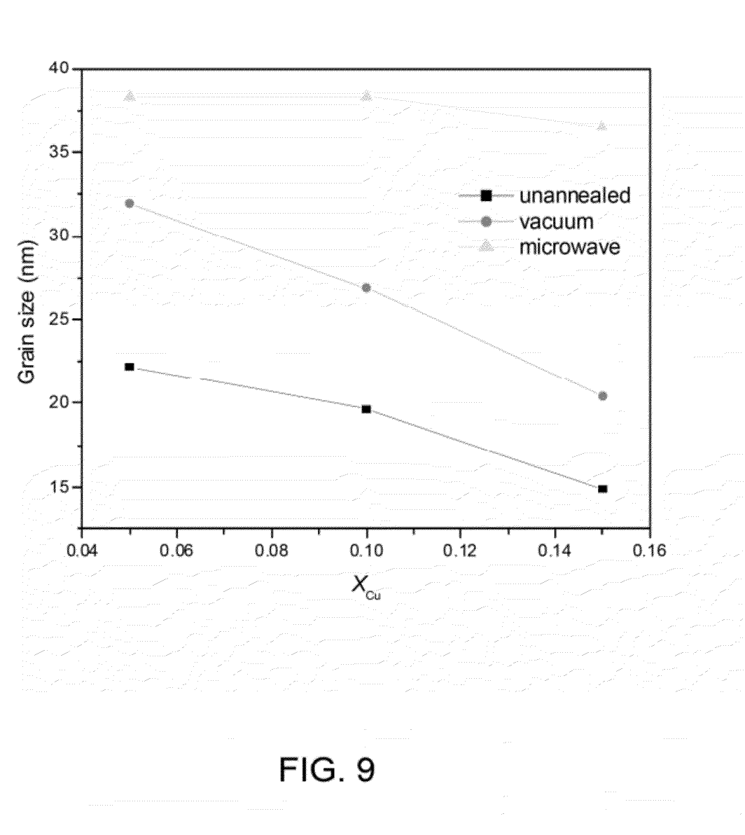

FIG. 9 shows the grain size of Ag of the Ag—Cu films as a function of atomic fraction of Cu (X_{Cu}). The as-deposited sample showed a decrease in grain size of Ag with increase in the Cu concentration. It is seen from the figure that addition of copper hinders the Ag grain growth. When the films were annealed in vacuum at 200° C. there was an increase in the grain sizes of Ag. However, grain sizes were maximum when the films were microwave annealed, and it almost remained the same with increasing Cu concentration. Thus, the microwave process induces a better grain growth and subsequent better electrical conductivity. This can be correlated with the fact that microwaves offer greater volumetric heating than conventional heating methods. Also, the deeper penetration of the microwaves into the Ag—Cu films might be a reason for better grain growth. Another advantage of microwave annealing was that the processing temperature was low and a much shorter time was required. Further, the simplicity of the microwave annealing process may provide an efficient and low-cost way to produce thin films with large areas.

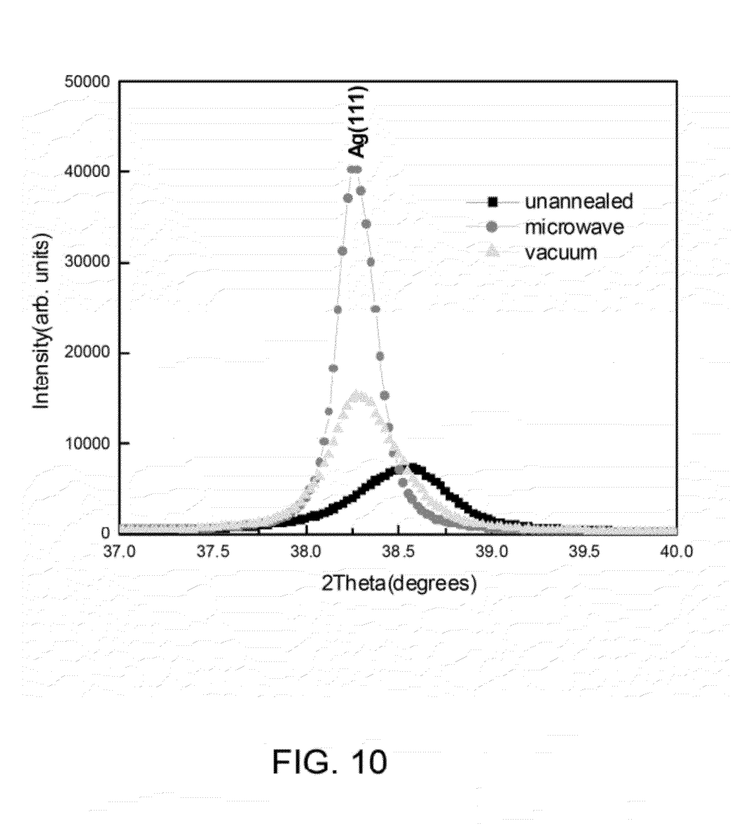

FIG. 10 shows the results from X-ray diffraction analysis of the as-deposited and annealed Ag—Cu alloy thin films: thermal anneal and microwave anneal. The plots show that a one-minute microwave anneal produces larger grain than a thirty minute thermal anneal. Hence the microwave anneal is a more energy efficient processing technique.

All of the methods disclosed and claimed herein can be made and executed without undue experimentation in light of the present disclosure. While the systems and methods of this invention have been described in terms of preferred embodiments, it will be apparent to those of skill in the art that variations may be applied to the methods and in the steps or in the sequence of steps of the method described herein without departing from the concept, spirit and scope of the invention. In addition, modifications may be made to the disclosed systems and components may be eliminated or substituted for the components described herein where the same or similar results would be achieved. All such similar substitutes and modifications apparent to those skilled in the art are deemed to be within the spirit, scope, and concept of the invention as defined by the appended claims.

### REFERENCES

Ahn, J., Lee, J., Kim, Y., and Ahn B.; Current Applied Physics, Volume 2, Issue 2, April 2002, 135-139
Alford, T. L., Feldman, L. C., and Mayer, J. W.; Fundamentals of Nanoscale Film Analysis (Springer, New York, 2008)
Alford, T. L., Thompson, D. C., Mayer, J. W., and Theodore, N. David; J Appl Phys, 106, 114902 (2009)
Bergmann, R. B., Oswald, G., Albrecht, M., Gross, V.; Sol Energy Mater Sol Cells 1997; 46:147-55
Fong. S. C., Wang, C. Y., Chang, T. H., and Chin, T. S.; Appl Phys Lett, 94, 102104 (2009)
Huang, Guoyin, Xi, Zhenqiang, Yang, Deren; Vacuum 80 (2006), 415-420
Hultman, L., Robertsson, A., Hentzell, H T G, Engstrom, I., Psaras, P. A.; J Appl Phys 1987; 62:3647-55
Ishikawa, K., Ozawa, M., Oh, C., Matsumura M.; Jpn J Appl Phys 1998; 37:731-6
Kakkad, R., Smith, J., Lau, W. S., Fonash, S. J., Kerns, R.; J Appl Phys 1989; 65:2069-72
Kinsbron, E., Sternheim, M., Knoell, R.; Appl Phys Lett 1983; 42:835-7
Lee, Y., Hsueh, F., Huang, S., Kowalski, J., Cheng, A., Koo, A., Luo, G., and Wu, Ching-Yi; IEEE Electron Device Letters, vol. 30, no. 2, February 2009
Matsuyama, T., Terada, N., Baba T., Sawada T., Tsuge S., Wakisaka K., et al.; J Non-Cryst Solids 1996; 198-200:940-4
Mayer, J. W. and Lau, S. S.; Electronic Materials Science: For Integrated Circuits in Si and GaAs (Macmillan, New York, 1990)
Metaxas, A. C. and Meredith, R. J.; Industrial Microwave Heating, IEEE Power Engineering Series 4 (Peter Peregrinus, London, 1983)
Poweleit, C. D., Gunther, A., Goodnick, S., and Menendez, Jose; Appl Phys Lett, VOLUME 73, NUMBER 16, 1998
Thompson, D. C., Decker, J., Alford, T. L., Mayer, J. W., and Theodore, N. David; Mater. Res. Soc. Symp. Proc. Vol. 989
Woo, Y., Kang, K., Jo. M., Jeon, J., and Kim, Miyoung; Appl Phys Lett, 91, 223107 (2007)

What is claimed is:

1. A system configured to anneal comprising:
a microwave emitter configured to emit a microwave at a single frequency during an anneal time;
an anneal unit to be annealed, the anneal unit having a top side, a bottom side, and one or more edge sides; and
a susceptor configured to absorb microwave energy, where the susceptor is adjacent to the one or more edge sides and at the bottom side of the anneal unit.

2. The system of claim 1, where the single frequency is 2.45 GHz.

3. The system of claim 1, where the anneal unit comprises a cylindrical substrate.

4. The system of claim 1, the cylindrical substrate comprising a dopant.

5. The system of claim 5, the dopant selected from the group consisting of arsenic (As), boron (B), silicon (Si), and aluminum (Al).

6. The system of claim 1, the cylindrical substrate substantially comprising Si.

7. The system of claim 1, the susceptor comprising silicon carbide (SiC).

8. The system of claim 1, the susceptor selected from the group consisting of SiC-coated alumina, magnesium oxide (MgO) coated alumina, SiC coated quartz, and MgO coated quartz.

9. The system of claim 1, where the anneal time is less than two minutes.

10. The system of claim 1, the system configured to heat the top side of the cylindrical substrate to at least 600° C.

11. The system of claim 1, further comprising a temperature measuring device.

12. The system of claim 1, where the anneal unit comprises a metal alloy thin film.

13. The system of claim 12, the metal alloy thin film comprising silver (Ag) and copper (Cu).

14. A method for annealing comprising:
receiving an anneal unit having a top side, a bottom side, and one or more edge sides;
arranging a susceptor configured to absorb microwave energy such that the susceptor is adjacent to the one or more edge sides and the bottom side of the anneal unit;
starting a single-frequency microwave emitter configured to heat both the susceptor and the anneal unit during an anneal time; and
stopping the single-frequency microwave emitter after the top side of the anneal unit has reached a specified temperature.

15. The method of claim 14, where the single frequency is 2.45 GHz.

16. The method of claim 14, where the anneal unit comprises a cylindrical substrate.

17. The method of claim 14, the cylindrical substrate comprising a dopant.

18. The method of claim 17, the dopant selected from the group consisting of arsenic (As), boron (B), silicon (Si), and aluminum (Al).

19. The method of claim 14, the cylindrical substrate substantially comprising Si.

20. The method of claim 14, the susceptor comprising silicon carbide (SiC).

21. The method of claim 14, the susceptor selected from the group consisting of SiC-coated alumina, magnesium oxide (MgO) coated alumina, SiC coated quartz, and MgO coated quartz.

22. The method of claim 14, where the anneal time is less than two minutes.

23. The method of claim 14, where the specified temperature is at least 600° C.

24. The method of claim 14, further comprising measuring the temperature on the top side of the substrate.

25. The method of claim 14, where the anneal unit comprises a metal alloy thin film.

26. The method of claim 25, the metal alloy thin film comprising silver (Ag) and copper (Cu).
